(19) United States
(12) Patent Application Publication
(10) Pub. No.: US 2026/0282270 A1
(43) Pub. Date: Sep. 17, 2026

(54) COOLING MODULE

(71) Applicant: SENAO NETWORKS, INC., TAOYUAN (TW)

(72) Inventors: Chia-Wei CHANG, TAOYUAN (TW); Chia-Yu HSIEH, TAOYUAN (TW); Li-Chun JAN, TAOYUAN (TW)

(21) Appl. No.: 19/329,867

(22) Filed: Sep. 16, 2025

(30) Foreign Application Priority Data
Mar. 11, 2025 (TW) 114108881

(51) Int. Cl. H05K 7/20; H05K 1/02

(52) U.S. Cl. CPC H05K 7/20145; H05K 1/0203; H05K 7/20154

(57) ABSTRACT

A cooling module for cooling the components of a computer are provided. The cooling module includes a substrate, a central processing unit, and a heat sink. The central processing unit is disposed on the substrate. The heat sink is disposed on the substrate close to the central processing unit to assist in heat dissipation of the central processing unit. A partially hollow space in the heat sink defines a cold channel, and the cold channel penetrates the heat sink in the same direction as a direction of discharging hot air already arranged in the computer. In this way, the cooling module can effectively cool the component of the computer without affecting product specifications.

### CROSS-REFERENCE TO RELATED APPLICATION

This application claims priority to Tiawan Patent Application No. 114108881 filed on Mar. 11, 2025, the contents of which are incorporated herein by reference in its entirety.

### BACKGROUND OF THE INVENTION

### Field of the Invention

The present invention relates to a cooling module, and in particular, relates to a cooling module for cooling components of a computer.

### Descriptions of the Related Art

With the development of information technology, people's demands for information service are expanding day by day, and the requirements for information transmission are also increasing continuously. The electronic products tend to be compact in design, and thus how to effectively dissipate the heat generated by components in a limited space to meet the heat resistance standard is one of the critical keys in products development.

For example, referring to FIG. 1A to FIG. 1C, there are shown schematic views of the initial configuration in the process of developing a smart NIC card by the applicants. In order to facilitate the use of end users, it is necessary to place Quad Small Form-factor Pluggable (called QSFP for short) 2 at the most downstream I/O. Because the airflow F flowing through the QSFP all comes from the upstream central processing unit (CPU) and the heat sink 4 of the CPU, in the analysis of the flow field of the whole smart NIC card, it is found that the temperature of the airflow discharged by the CPU is as high as 74.1° C., which has exceeded the heat resistance standard of 70° C. for QSFP. However, it will affect the market acceptance if the product specification is lowered to solve the difficulty of excessively high temperature.

To sum up, there is an urgent need for other solutions to solve the above difficulties. It shall be additionally noted that the above technical contents are arrangements adopted by the applicants in the development process to help understand the problems to be solved by the present invention, and should not be construed as being published or well known in the art.

### SUMMARY OF THE INVENTION

An objective of the present invention is to provide a cooling module which can effectively cool components of a computer without affecting product specifications (for example, lowering specifications), and it is also preferably a more cost-effective solution as compared to other cooling methods, making it a highly anticipated improvement in the art.

In order to achieve the above objective, a cooling module for cooling elements of a computer according to the present invention comprises a substrate, a central processing unit and a heat sink. The central processing unit is disposed on the substrate. The heat sink is disposed on the substrate and abuts against the central processing unit to assist in heat dissipation of the central processing unit. A partially hollow space in the heat sink defines a cold channel, and the cold channel penetrates the heat sink in the same direction as a discharge heat flow direction already arranged in the computer.

In order to achieve the above objective, another cooling module for cooling elements of a computer according to the present invention comprises a substrate, a central processing unit, a heat sink and an independent cold channel. The central processing unit is disposed on the substrate. The heat sink is disposed on the substrate and abuts against the central processing unit to assist the heat dissipation of the central processing unit. The independent cold channel may be manufactured separately or it may be partially or completely arranged on the substrate, and the independent cold channel is disposed adjacent to the heat sink in the same direction as a discharge heat flow direction already arranged in the computer.

As described above, the cooling module provided according to the present invention modifies the existing CPU cooling mechanism of the computer, e.g., reduces the temperature of the airflow flowing to a component to be cooled by using the heat sink area and the heating dissipating airflow direction of the CPU, thereby enhancing the cooling ability for the component to be cooled. In this way, the components to be cooled can meet the heat resistance standard without changing the specifications, and it is preferably a more cost effective solution as compared to other methods of modifying the heat sink material and the airflow intensity, thereby effectively improving the competitiveness of products.

In an embodiment, the cooling module according to the present invention may further comprise a fan disposed on the substrate or disposed on a portion of the heat sink and located upstream of the discharge heat flow direction, and the fan is at least one centrifugal fan or axial fan.

In an embodiment, the cooling module according to the present invention further comprises a component to be cooled, which is partially disposed on the substrate, located downstream of the discharge heat flow direction, and located downstream of the heat sink.

In an embodiment, in the cooling module according to the present invention, an extension axis of the cold channel is basically or nearly the same as an extension axis of the component to be cooled, so that the air flow through the cold channel flows directly to the component to be cooled.

In an embodiment, the cooling module according to the present invention further comprises a flow guiding channel that is disposed on the substrate, the flow guiding channel defines a first opening and a second opening that are apart from each other, the first opening faces toward the cold channel, and the second opening faces toward the component to be cooled.

In an embodiment, in the cooling module according to the present invention, the partially hollow space is located in a lower half of the heat sink, at a position abutting against or close to the substrate, or is located at an upper half of the heat sink, at a position having a distance from the substrate, or extends from the lower half to the upper half close to or beyond the top of the heat sink.

In an embodiment, in the cooling module according to the present invention, when the cold channel defined by the partially hollow space is tightly disposed on the substrate, the substrate located below the cold channel further comprises a groove to increase a cross-sectional area of the air flow.

In an embodiment, in the cooling module according to the present invention, the partially hollow space is disposed at an entire side portion of the heat sink, so that a width of the heat sink is reduced, or the partially hollow space cuts the heat sink so that the heat sink are separated into two blocks.

In an embodiment, in the cooling module according to the present invention, the heat sink comprises an insulation material that completely or partially encircles the cold channel.

### BRIEF DESCRIPTION OF THE DRAWINGS

FIG. 1A is a schematic perspective view of the initial configuration in the development process by the applicants;

FIG. 1B is a schematic cross-sectional view taken along the section line A-A′ in FIG. 1A;

FIG. 1C is a graph showing the detection result of the airflow temperature in FIG. 1B;

FIG. 2A is a schematic perspective view of a cooling module according to an embodiment of the present invention;

FIG. 2B is a schematic cross-sectional view taken along the section line B-B′ in FIG. 2A;

FIG. 2C is a graph showing the detection result of the airflow temperature of FIG. 2B;

FIG. 2D is a cross-sectional perspective view taken along the section line B-B′ in FIG. 2A;

FIG. 2E is a schematic cross-sectional view taken along the section line B-B′ in FIG. 2A according to another embodiment of the present invention;

FIG. 3 is a schematic perspective view of a cooling module according to an embodiment of the present invention;

FIG. 4A is a schematic perspective view of a cooling module according to an embodiment of the present invention;

FIG. 4B is a cross-sectional perspective view taken along the section line C-C′ in FIG. 4A; and

FIG. 5 is a schematic perspective view of a cooling module according to an embodiment of the present invention.

### DESCRIPTION OF THE PREFERRED EMBODIMENT

Hereinafter, specific embodiments according to the present invention will be specifically described. However, the present invention may be practiced in many different forms of embodiments without departing from the spirit of the present invention, and the scope claimed in the present invention should not be interpreted as being limited to what stated in the specification.

Terms such as “first” and “second” are used herein to describe and distinguish various components or assemblies, rather than indicating the necessary order or priority of these components or assemblies. In addition, the orientations (such as front, back, up, down, left, right, etc.) described herein are relative orientations, which can be defined according to the placement state of the cooling module in the computer. These orientations do not indicate or imply that the cooling module must be constructed or operated in a specific direction, and they cannot be construed as a limitation of the present invention.

The relative dimensional proportions, sizes and shapes in the drawings are depicted for convenience and are not intended to be limiting.

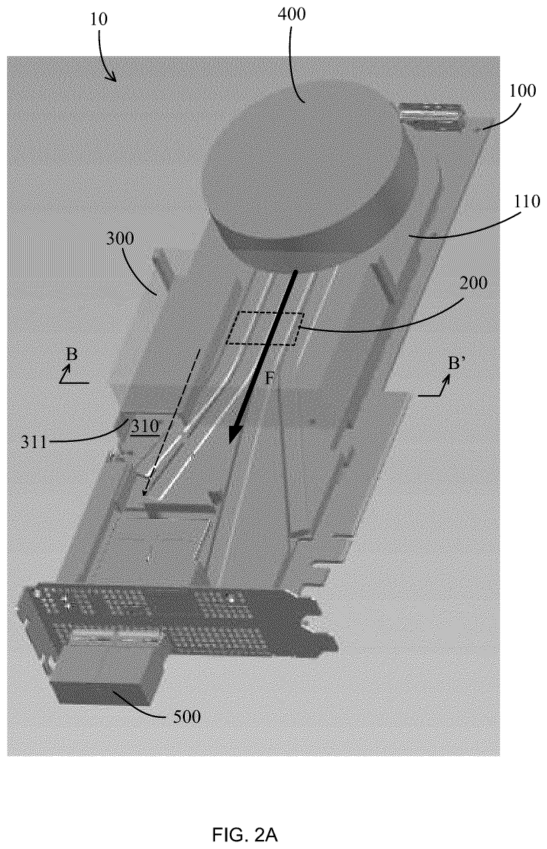

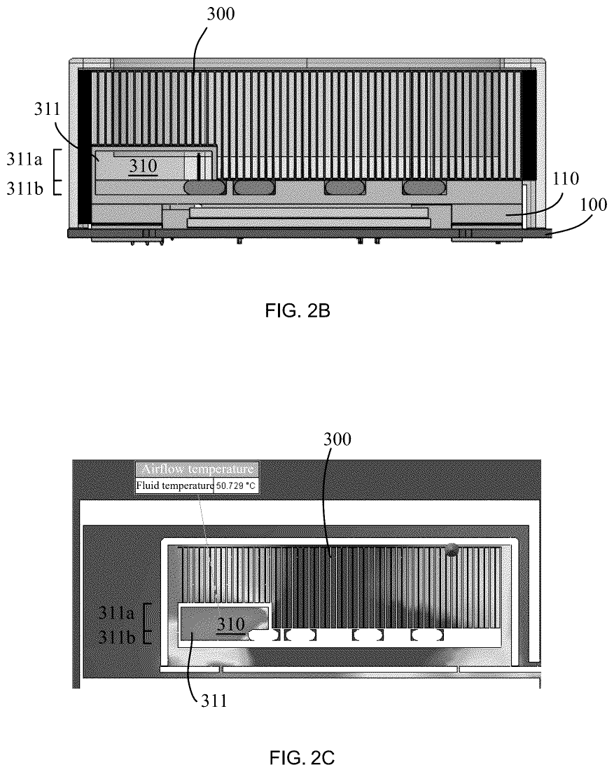

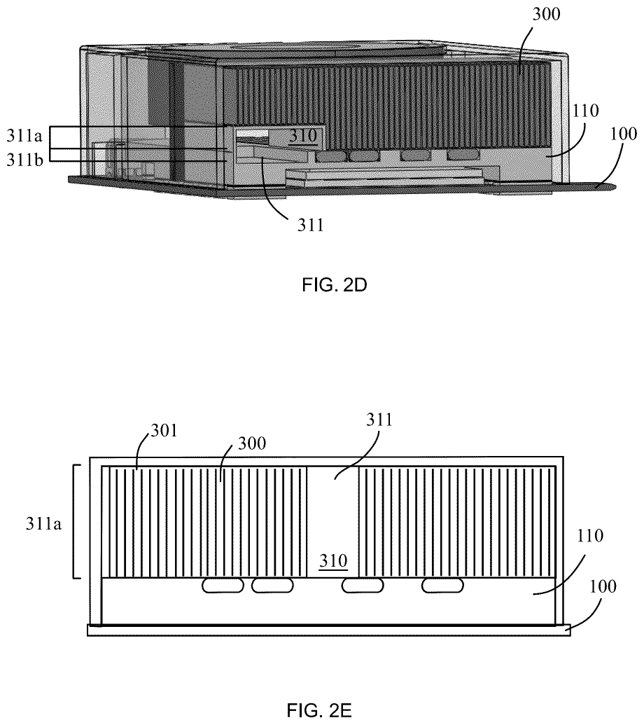

Referring to FIG. 2A, there is shown a schematic view of a cooling module 10 according to an embodiment of the present invention. The cooling module 10 may comprise a substrate 100, a central processing unit 200 and a heat sink 300, and the technical contents of these structures will be described in sequence as follows.

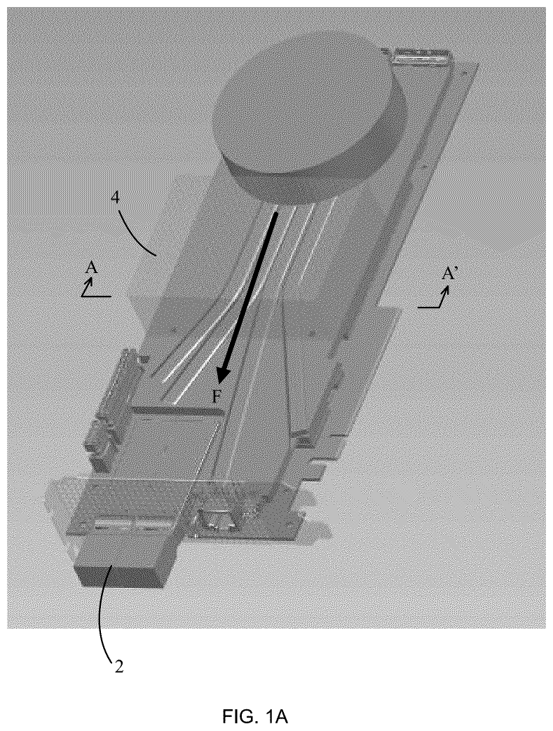

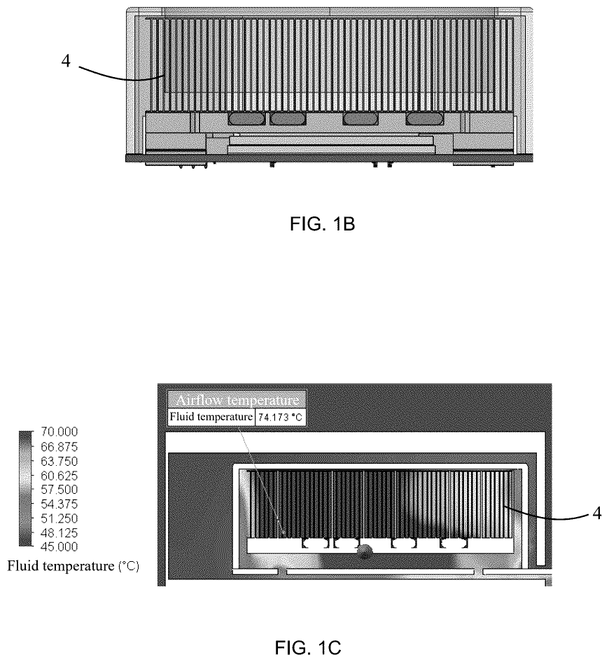

The substrate 100 is a board for arranging circuits and fixing various components and elements in a computer, including a heat dissipation module baseboard 110 for further assisting in fixing the heat dissipation module, and the central processing unit 200 is arranged on the substrate 100. In order to reduce the temperature rising during the operation of the central processing unit 200, the heat sink 300 is disposed abutting against the central processing unit 200 and meanwhile detachably fixed on the substrate 100 or the heat dissipation module baseboard 110 of the substrate 100. FIG. 1A to FIG. 1C show a state under test. In this test state, the discharge heat flow F in the computer passes through the heat sink 4 of the CPU before flowing through other components 2 (for example, the QSFP). As can be known from FIG. 1C, the temperature of the airflow discharged from the CPU is as high as 74.1° C., which exceeds the heat resistance standard of 70° C. for QSFP, and this may lead to poor operation and damage of QSFP or have other safety concerns.

Therefore, as shown in FIG. 2A to FIG. 2D, in a first embodiment of the present invention, the heat sink 300 is provided with a partially hollow space 310 that defines a cold channel 311. The heat sink used in this embodiment may be an extruded block-shaped heat sink formed by arranging and combining a plurality of sheet-shaped fins, and the partially hollow space 310 refers to shortening the length of part of the sheet-shaped fins or completely removing the sheet-shaped fins in some areas so that the heat sink 300 generates a hollow space viewed from the perspective of a block. The partially hollow space 310 shown in the figure is located on the left side of the lower half of the heat sink 300, at a position close to the substrate 100, but it is not limited thereto. The partially hollow space 310 may also be located in the middle or right side of the lower half of the heat sink 300, at a position abutting against or close to the substrate 100. Alternatively, the partially hollow space 310 may also be disposed anywhere in the upper half of the heat sink 300, at a distance from the substrate 100. Different arrangements are possible based on the configuration of the computer that can be known to those of ordinary skill in the art. In the embodiment shown in the figures, when the discharge heat flow F flows from the upper part to the lower part in the figures, the temperature of airflow passing through the partially hollow space 310 may be reduced to 50.7° C. As compared to the configuration without the cold channel 311, it is obvious that a large margin is available to further take away the heat emitted by other components in the lower part.

In an embodiment, the partially hollow space 310 may be provided only with a section 311a and a sufficiently low exhaust temperature can be realized. In another embodiment, referring to FIG. 2D, a section 311b may be further provided on the substrate 100 supporting the heat sink 300 (e.g., on the heat dissipation module baseboard 110) according to the heat dissipation requirements or when the heat sink 300 has sufficient temperature margin, and the section 311b is connected with the partially hollow space 310 of the heat sink 300 originally disposed adjacent to the substrate 100, thereby increasing a cross-sectional area of the heat dissipation air flow and enhancing the cooling effect.

In an embodiment, as shown in FIG. 2E, the section 311a of the partially hollow space 310 may extend from the substrate 100 close to or beyond the top 301 of the heat sink 300. In other words, a part of the heat sink 300 may be completely removed, so that the substrate 100 or the heat dissipation module baseboard 110 thereof can be directly exposed (which can still be shielded by an external cover plate after assembly) and a width of the heat sink 300 is reduced, or the heat sink 300 are divided into left and right blocks, without being limited thereto.

The configuration of the heat sink 300 is not limited by the above contents or drawings, and the heat sink 300 may have different fin gaps, and the fin gaps that can be implemented may range from 0.8 mm to 10 mm. When the fin gap is 1.0 mm, the static pressure (P) of the discharge heat flow F is 4.52 mm H₂0 (0.178 in H₂0), and the flow rate (Q) of the discharge heat flow F is 55.76 CFM. When the fin gap is 4.5 mm, the static pressure (P) of the discharge heat flow F is 0.95 mm H₂0, and the flow rate (Q) of the discharge heat flow F is 18.36 CFM. In addition, the material of the heat sink 300 may be composed of aluminum, aluminum alloy, aluminum-magnesium alloy, copper and copper alloy, and the heat sink 300 may also be a forged heat sink which can also form the partially hollow space 310.

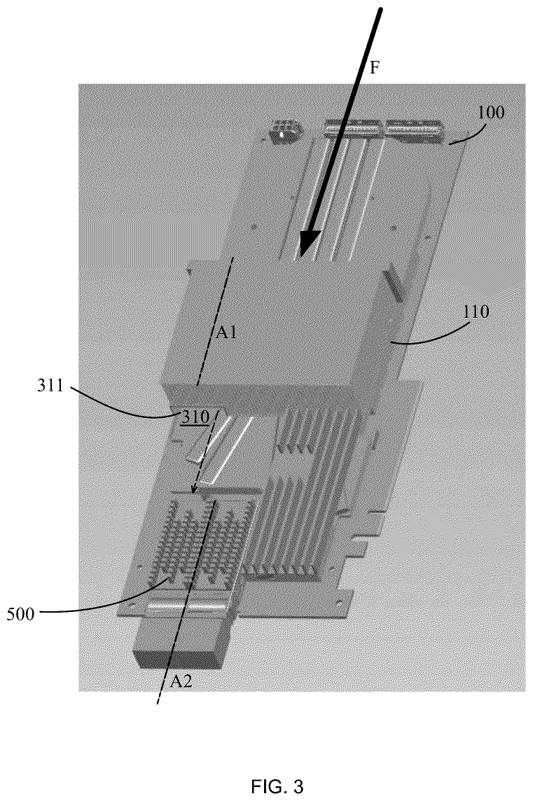

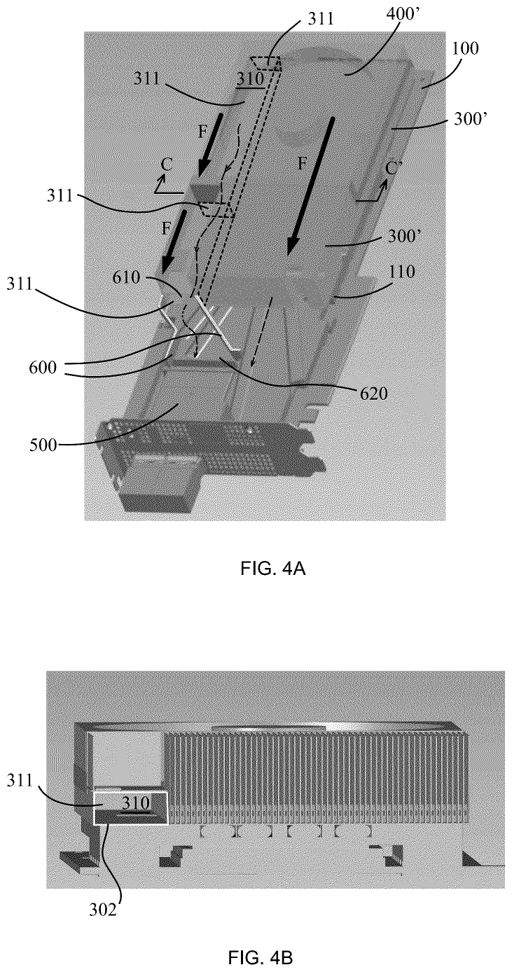

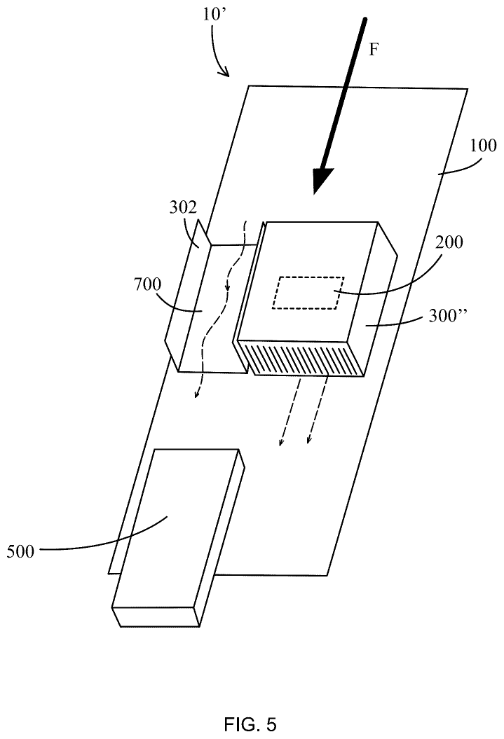

As shown in FIG. 2A, in an embodiment, a fan 400 may be arranged in the same module as the cooling module 10, and directly provides a discharge heat flow F flowing through the CPU 200. The fan 400 may be a single centrifugal fan, one or two axial fans, or other types or numbers of fans. Alternatively, as shown in FIG. 3, in an embodiment, a fan may not be provided in the cooling module 10, the cooling module 10 may be arranged at the preset place through which the discharge heat flow F flows in the computer. Alternatively, as shown in FIG. 4A, in an embodiment, when an axial fan 400′ is provided, a heat sink 300′ may further extend below the axial fan 400′, and the heat sink 300′ below the axial fan 400′ may also have a partially hollow space 310 which forms a cold channel 311 that is in fluid communicated with the downstream of the CPU 200.

In an aspect shown herein, a component 500 to be cooled may be arranged on the substrate 100 or the heat dissipation module baseboard 110 of the substrate 100, and it is the same module as the cooling module 10, or it may be arranged as a different module from the cooling module 10, without being limited thereto. Whether it is a part of the cooling module 10 or not, in the aspect shown herein, the component 500 to be cooled is located downstream of the flow direction of the discharge heat flow F, more specifically, the component 500 is located below the CPU 200 (although the component 500 to be cooled located downstream is shown below the CPU 200 and the heat sink 300 in the figure, it is not limited thereto, and the component 500 to be cooled may also be located above the CPU 200 and the heat sink 300 according to different placement directions or the flow field direction of the discharge heat flow F preset in the computer). When the component 500 to be cooled is a QSFP, according to the measurement results, the temperature of QSFP may rise to 77.4° C. when no cold channel is provided, and the temperature of QSFP may be reduced to 66.5° C. when the arrangement of FIG. 2A is adopted as shown in FIG. 2C.

Corresponding to the arrangement of the component 500 to be cooled, an extension axis A1 of the cold channel 311 defined by the partially hollow space 310 may be substantially coaxial or completely coaxial with an extension axis A2 of the component 500 to be cooled (not shown). That is, the airflow flowing out of the cold channel 311 may directly correspond to and flow toward the component 500 to be cooled. For example, when the component 500 to be cooled is arranged on the left side (the left side as shown in FIG. 3), the cold channel 311 is arranged on the left side (the left side in the same figure) of the heat sink 300, without being limited thereto. An extension axis A1 of the cold channel 311 defined by the partially hollow space 310 and an extension axis A2 of the component 500 to be cooled may also be spaced apart, and the airflow can still generate the cooling effect.

In an embodiment, as shown in FIG. 4A, a flow guiding channel 600 may be further provided between the cold channel 311 and the component 500 to be cooled. The flow guiding channel 600 is disposed on the substrate 100 or the heat dissipation module baseboard 110 of the substrate 100, and in an embodiment, it may be composed of two non-linear baffles to define a first opening 610 and a second opening 620 which is apart from the first opening 610. The first opening 610 may be arranged to be directly connected to the cold channel 311, or to be adjacent to or close to the cold channel 311. According to the shape difference of the component 500 to be cooled, the second opening 620 may be disposed adjacent to or close to the component 500 to be cooled as much as possible. In this way, after leaving the cold channel 311, the discharge heat flow F will directly and intensively flow to the component 500 to be cooled along the flow guiding channel 600 without being lost in the process, thereby enhancing the cooling effect.

Referring to FIG. 4B, in an embodiment, the heat sink 300 may be further provided with an thermal-insulating material 302 which may be for example an insulation coating or an insulation sheet, and the thermal-insulating material 302 completely or partially encircles the cold channel 311. In this way, the discharge heat flow F can be further prevented from absorbing heat through the heat sink 300 when passing through the cold channel 311, and thus maintained at a lower temperature.

Referring to FIG. 5, there is shown a schematic view of a cooling module 10′ according to an embodiment of the present invention. The cooling module 10′ may comprise a substrate 100, a central processing unit 200 and a heat sink 300″. The difference between the cooling module 10′ and the cooling module 10 is that the cooling module 10′ includes an independent cold channel 700, the independent cold channel 700 may be independently manufactured and it may be partially or completely arranged on the substrate 100 or the heat dissipation module baseboard 110 of the substrate 100 at the downstream of the discharge heat flow F. In an embodiment, the independent cold channel 700 is arranged adjacent to the heat sink 300″, which has the advantage that the heat sink 300″ may be manufactured in the same way as the heat sink 4 (possibly only with a smaller width), and it is not necessary to provide the partially hollow space 310 on the heat sink 300″. Moreover, the independent cold channel 700 may be directly made of an thermal-insulating material 302 for example, so that the discharge heat flow F passing through the independent cold channel 700 is hardly influenced by the heat sink 300″ and thus the expected cooling effect can be achieved without greatly affecting the cost.

With the above arrangements, the cooling module of the present invention makes use of the situation that the heat sinks of the CPU have heat dissipation margin to make the component to be cooled meet the heat resistance standard without greatly changing the specifications, and it effectively enhances the competitiveness of products as a more cost effective and simple solution as compared to other methods of modifying the heat sink material, the fine arrangement of the heat sinks, and the fan airflow intensity.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A cooling module for cooling the elements of a computer, comprising:
a substrate;
a central processing unit disposed on the substrate; and
a heat sink disposed on the substrate and abut against the central processing unit to assist in heat dissipation of the central processing unit;
wherein a partially hollow space in the heat sink defines a cold channel, and the cold channel penetrates the heat sink in the same direction as a discharge heat flow direction already arranged in the computer.

2. The cooling module according to claim 1, further comprising: a fan disposed on the substrate or disposed on a portion of the heat sink and located upstream of the discharge heat flow direction, wherein the fan is at least one centrifugal fan or axial fan.

3. The cooling module according to claim 1, further comprising: a component to be cooled partially disposed on the substrate and located downstream of both the discharge heat flow direction and the heat sink.

4. The cooling module according to claim 3, wherein an extension axis of the cold channel is substantially coaxial with an extension axis of the component to be cooled, so that the air flow through the cold channel flows directly to the component to be cooled.

5. The cooling module according to claim 3, wherein an extension axis of the cold channel and an extension axis of the component to be cooled are at a distance from each other.

6. The cooling module according to claim 5, further comprising: a flow guiding channel disposed on the substrate and defining a first opening and a second opening that are apart from each other, wherein the first opening faces toward the cold channel, and the second opening faces toward the component to be cooled.

7. The cooling module according to claim 1, wherein the partially hollow space is located in a lower half of the heat sink and at a position close to the substrate, or is located at an upper half of the heat sink and at a position having a distance from the substrate, or extends from the lower half to the upper half and close to or beyond a top of the heat sink.

8. The cooling module according to claim 7, wherein the cold channel defined by the partially hollow space is disposed on the substrate, the substrate located below the cold channel further comprises a groove to increase a cross-sectional area of the air flow.

9. The cooling module according to claim 1, wherein the partially hollow space is disposed at a side portion of the heat sink so that a width of the heat sink is reduced, or the partially hollow space extends across the heat sink so that the heat sink is divided into two blocks.

10. The cooling module according to claim 1, wherein the heat sink comprises an thermal-insulating material that completely or partially encircles the cold channel.

11. A cooling module for cooling the elements of a computer, comprising:
a substrate;
a central processing unit disposed on the substrate;
a heat sink abut against or close to the central processing unit to assist the heat dissipation of the central processing unit; and
an independent cold channel disposed adjacent to the heat sink, such that a discharge heat flow in the computer flows through the independent cold channel and the heat sink at the same time.
